(19) United States
(12) Patent Application Publication
(10) Pub. No.: US 2009/0320908 A1
(43) Pub. Date: Dec. 31, 2009

(54) PHOTOVOLTAIC MODULE WITH DRAINAGE FRAME

(75) Inventors: Jonathan Botkin, El Cerrito, CA (US); Simon Graves, Berkeley, CA (US); Matthew Culligan, Berkeley, CA (US)

Correspondence Address: Dicke, Billig & Czaja, PLLC, Attn: SP Matters, 100 South Fifth Street, Suite 2250, Minneapolis, MN, 55402, US

(73) Assignee: SunPower Corp., San Jose, CA (US)

(21) Appl. No.: 12/492,838

(22) Filed: Jun. 26, 2009

Related U.S. Application Data
(60) Provisional application No. 61/076,497, filed on Jun. 27, 2008.

(51) Int. Cl. H01L 31/048; H01L 21/50

(52) U.S. Cl. 136/251; 438/64; 257/E21.499

(57) ABSTRACT

A PV module including a PV device and a frame. The PV device has a PV laminate maintaining a plurality of PV cells at a front face. The PV cells are arranged in rows, including a first row adjacent an edge of the PV laminate. Adjacent ones of the PV cells of the first row are separated by a column spacing. The frame is assembled to the PV laminate, and includes a frame member having a ledge and a plurality of spaced fingers that are connected to, and spaced from, the ledge. The PV laminate is mounted between the ledge and the fingers, with one of the fingers being aligned with one of the column spacings. The PV module facilitates liquid drainage between the spaced fingers. Further, the fingers minimize shading effects presented by the frame member, thereby enhancing a GCR of the PV module.

### PRIORITY DATA

This application claims priority under 35 U.S.C. §119(e)(1) to U.S. Provisional Patent Application Ser. No. 61/076,497, filed Jun. 27, 2008, entitled “Photovoltaic Module with Drainage Frame”, and bearing Attorney Docket No. S0135/S812.105.101; and the entire teachings of which are incorporated herein by reference.

### CROSS-REFERENCE TO RELATED APPLICATIONS

This application also relates to U.S. application Ser. No. ______ entitled “Ballasted Photovoltaic Module and Module Arrays” and bearing attorney docket number S0131US/S812.101.102; U.S. application Ser. No. ______ entitled “Photovoltaic Module Kit Including Connector Assembly for Non-Penetrating Array Installation” and bearing attorney docket number S0132US/S812.102.102; U.S. application Ser. No. ______ entitled “Photovoltaic Module with Removable Wind Deflector” and bearing attorney docket number S0133US/S812.103.102; and U.S. application Ser. No. ______ entitled “Photovoltaic Module and Module Arrays” and bearing attorney docket number S0134US/S812.104.102; all of which were filed on even date herewith and the teachings of each of which are incorporated herein by reference.

### STATEMENT REGARDING FEDERALLY SPONSORED RESEARCH OR DEVELOPMENT

This invention was made with Government support under Contract No. DE-FC36-07GO17043 awarded by the United States Department of Energy. The Government has certain rights in this invention.

### BACKGROUND

The present disclosure relates to solar roof tiles. More particularly, it relates to photovoltaic modules with drainage features and methods of manufacturing the same.

Solar power has long been viewed as an important alternative energy source. To this end, substantial efforts and investments have been made to develop and improve upon solar energy collection technology. Of particular interest are industrial- or commercial-type applications in which relatively significant amounts of solar energy can be collected and utilized in supplementing or satisfying power needs.

Solar photovoltaic technology is generally viewed as an optimal approach for large scale solar energy collection, and can be used as a primary and/or secondary (or supplemental) energy source. In general terms, solar photovoltaic systems (or simply “photovoltaic systems”) employ solar panels made of silicon or other materials (e.g., III-V cells such as GaAs) to convert sunlight into electricity. More particularly, photovoltaic systems typically include a plurality of photovoltaic (PV) modules (or “solar tiles”) interconnected with wiring to one or more appropriate electrical components (e.g., switches, inverters, junction boxes, etc.). The PV module conventionally consists of a PV laminate or panel generally forming an assembly of crystalline or amorphous semiconductor devices electrically interconnected and encapsulated. One or more electrical conductors are carried by the PV laminate through which the solar-generated current is conducted.

Regardless of an exact construction of the PV laminate, most PV applications entail placing an array of PV modules at the installation site in a location where sunlight is readily present. This is especially true for commercial or industrial applications in which a relatively large number of PV modules are desirable for generating substantial amounts of energy, with the rooftop of the commercial building providing a convenient surface at which the PV modules can be placed. As a point of reference, many commercial buildings have large, flat roofs that are inherently conducive to placement of a PV module array, and are the most efficient use of existing space. While rooftop installation is thus highly viable, certain environment constraints must be addressed. For example, the PV laminate is generally flat or planar; thus, if simply “laid” on an otherwise flat rooftop, the PV laminate may not be optimally positioned/oriented to collect a maximum amount of sunlight throughout the day. Instead, it is desirable to tilt the PV laminate at a slight angle relative to the rooftop (i.e., toward the southern sky for northern hemisphere installations, or toward the northern sky for southern hemisphere installations). Further, possible PV module displacement due to wind gusts must be accounted for, especially where the PV laminate is tilted relative to the rooftop as described above.

In light of the above, PV modules for commercial installations necessarily entail robust framework for maintaining the PV laminate relative to the installation surface (e.g., penetrating-type mounting in which bolts are driven through the rooftop to attach the framework and/or auxiliary connectors to the rooftop; non-penetrating mounting in which auxiliary components interconnect PV modules to one another; etc.). Thus, traditional PV modules employ an extruded aluminum frame that supports the entire perimeter of the corresponding PV laminate. A lip of the aluminum frame extends over and captures an upper surface of the PV laminate. Though well accepted, this assembly configuration can negatively affect long-term performance.

For example, airborne dust, dirt, and other debris are constantly being deposited onto the PV laminate. Rain and other moisture causes the deposited debris to accumulate. Unfortunately, the frame lip impedes drainage of moisture from the PV laminate surface. Instead, moisture will collect along the PV laminate, especially at the lowest point of the PV module. For example, with a south-tilted PV module, moisture (and entrained debris) will travel (via gravity) toward the southern frame portion, effectively pooling against the frame lip. As the moisture subsequently evaporates, it leaves behind dirt and debris. This soiling has the effect of shading nearby PV cells, and can thus significantly decrease performance of the PV module.

To perhaps address the above concerns, it has been suggested to machine cut several channels into the aluminum frame at one or more corners thereof, with the channels providing a region for liquid to drain off of the PV module. Once such device is believed to be available from Kyocera Corp., Solar Energy Division, of Kyoto, Japan. While potentially workable, the added manufacturing steps in forming the machined cuts renders the suggested approach prohibitively expensive. Further, other possible shading concerns presented by the frame lip remain unresolved.

In light of the above, a need exists for a cost effective PV module configuration incorporating drainage features.

### SUMMARY

Some aspects in accordance with principles of the present disclosure relate to a PV module including a PV device and a frame. The PV device has a PV laminate defining a perimeter and a front face, with the PV laminate maintaining a plurality of PV cells at the front face. In this regard, the plurality of PV cells are arranged in rows including a first row formed immediately adjacent a first perimeter edge of the PV laminate. Further, adjacent ones of the PV cells of the first row are separated by a column spacing. The frame is assembled to and maintains the PV laminate, and includes a first frame member having a ledge and a plurality of spaced fingers that are connected to, and spaced from, the ledge. Upon final assembly, the first perimeter edge of the PV laminate is mounted between the ledge and the fingers. As part of this mounting, one of the fingers provided with the frame member is aligned with one of the column spacings of the first row. The so-constructed PV module facilitates drainage, especially with tilted arrangements in which the first frame member is below other frame members, via water draining between the spaced fingers. Further, the aligned relationship of the finger(s) relative to the column spacing(s) minimizes shading effects presented by the first frame member, thereby enhancing a ground coverage ratio associated with the PV module. In some embodiments, the first frame member is entirely formed of plastic, such as an injection molded part. In other embodiments, the plurality of fingers are uniformly spaced along the first frame member, and are aligned with respective ones of the column spacings of the first row. In yet other embodiments, the fingers have a tapered shape, corresponding with a shape of the column spacing.

Other aspects in accordance with principles of the present disclosure relate to methods of making a PV module. The methods include providing a PV device including a PV laminate defining a perimeter and a front face. The PV laminate maintains a plurality of PV cells at the front face, with the cells arranged into rows including a first row formed immediately adjacent a first perimeter edge of the PV laminate. A frame is provided by, at least in part, molding a frame member from plastic. In this regard, the molded plastic frame member includes a ledge and a plurality of spaced fingers connected to, and spaced from, the ledge. The PV laminate is assembled to the frame by inserting the perimeter edge of the PV laminate between the ledge and the fingers. These, and related, methods of manufacturing present a highly cost-effective technique for making PV modules with drainage features on a mass-production basis in that no secondary operations, such as machine cutting, are required. In some embodiments, the frame member is injection molded. In other embodiments, an entirety of the frame is injection molded from plastic.

### BRIEF DESCRIPTION OF THE DRAWINGS

FIG. 1A is a perspective view portion of a photovoltaic module in accordance with principles of the present disclosure;

FIG. 1B is an exploded view of the photovoltaic module of FIG. 1A;

FIG. 2 is an enlarged, top view of a photovoltaic laminate portion of the photovoltaic module of FIG. 1A;

FIG. 3A is a perspective view of a frame member portion of the photovoltaic module of FIG. 1;

FIG. 3B is a cross-sectional view of the frame member of FIG. 3A, taken along the line 3B-3B;

FIG. 3C is a cross-sectional view of the frame member of FIG. 3A, taken along the line 3C-3C;

FIG. 3D is a top view of the frame member of FIG. 3A;

FIG. 4A is an enlarged, perspective view of a portion of the photovoltaic module of FIG. 1A;

FIG. 4B is a cross-sectional view of the photovoltaic module of FIG. 4A, taken along the line 4B-4B;

FIG. 4C is a cross-sectional view of the photovoltaic module of FIG. 4A, taken along the line 4C-4C;

FIG. 5 is a top view of the photovoltaic module of FIG. 1A; and

FIG. 6 is a side view of the photovoltaic module of FIG. 1A mounted to an installation surface.

### DETAILED DESCRIPTION

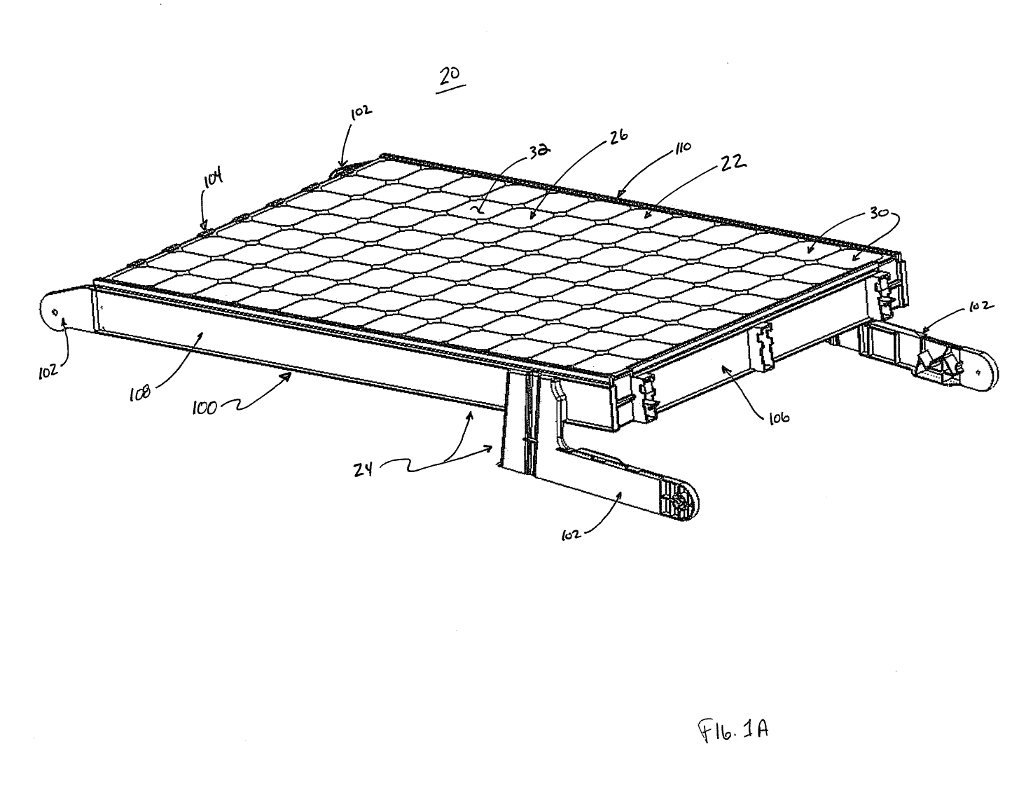

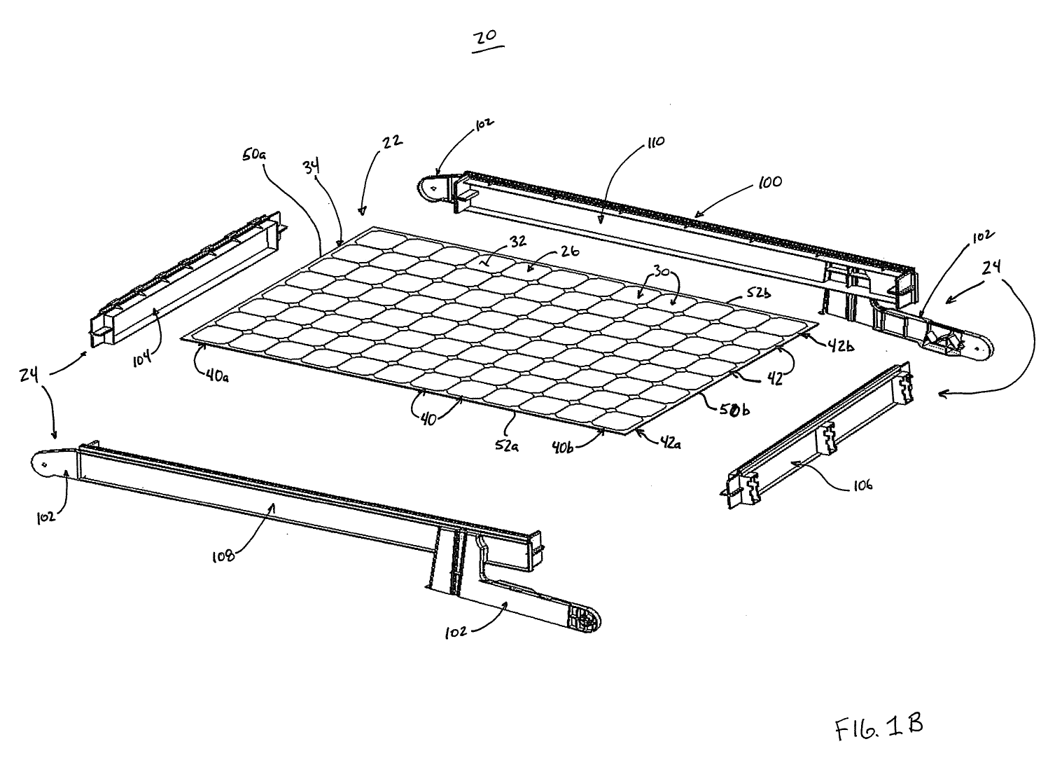

A photovoltaic (PV) module 20 in accordance with principles of the present disclosure is shown in FIGS. 1A and 1B. The PV module 20 includes a PV device 22 (referenced generally) and a frame 24. Details on the various components are provided below. In general terms, however, the PV device 22 includes a PV laminate 26 that is encased by the frame 24. In this regard, the frame 24 incorporates drainage feature(s) that allow liquid to naturally drain from a surface of the PV laminate 26, as well as minimize frame-caused shadowing of the PV laminate 26 thereby enhancing a ground coverage ratio (GCR) parameter of the PV module 20.

The PV device 22 can assume a variety of forms that may or may not be implicated by FIGS. 1A and 1B. For example, the PV device 22, including the PV laminate 26, can have any form currently known or in the future developed that is otherwise appropriate for use as a solar PV device. In general terms, the PV laminate 26 consists of an array of PV cells 30. A glass laminate may be placed over the PV cells 30 for environmental protection. In some embodiments, the PV cells 30 advantageously comprise backside-contact cells, such as those of the type available from SunPower Corp., of San Jose, Calif. As a point of reference, in backside-contact cells, wirings leading to external electrical circuits are coupled on the backside of the cell (i.e., the side facing away from the sun upon installation) for increased area for solar collection. Backside-contact cells are also disclosed in U.S. Pat. Nos. 5,053,083 and 4,927,770, which are both incorporated herein by reference in their entirety. Other types of PV cells may also be used without detracting from the merits of the present disclosure. For example, the photovoltaic cells 30 can incorporate thin film technology, such as silicon thin films, non-silicon devices (e.g., III-V cells including GaAs), etc. Thus, while not shown in the figures, in some embodiments the PV device 22 can include one or more components in addition to the PV laminate 26, such as wiring or other electrical components.

Regardless of an exact construction, the PV laminate 26 can be described as defining a front face 32 and a perimeter 34 (referenced generally in FIG. 1B). Additional components (where provided) of the PV device 22 are conventionally located at or along a back face of the PV laminate 26, with the back face being hidden in the views of FIGS. 1A and 1B.

The PV cells 30 are maintained at the front face 32 for receiving sunlight. With specific reference to FIG. 1B, the arrayed format of the PV cells 30 defines a plurality of rows 40 and a plurality of columns 42. For purposes of identification, the array of PV cells 30 can be described as including a first row 40a immediately proximate or adjacent a first perimeter end edge 50a of the PV laminate 26, and a second row 40b immediately proximate or adjacent an opposing, second perimeter end edge 50b. Similarly, a first column 42a is defined immediately proximate or adjacent a first perimeter side edge 52a, and a second column 42b is formed immediately adjacent an opposing, second perimeter side edge 52b. While FIG. 1B illustrates the PV laminate 26, and thus the arrayed PV cells 30, as having a rectangular form, other configurations are equally acceptable (e.g., the PV laminate 26 can have a square shape; the end edges 50a, 50b can be longer than the side edges 52a, 52b; etc.). Similarly, the number of PV cells 30 associated with the rows 40 and/or the columns 42 can be greater or lesser than the numbers reflected in FIG. 1A.

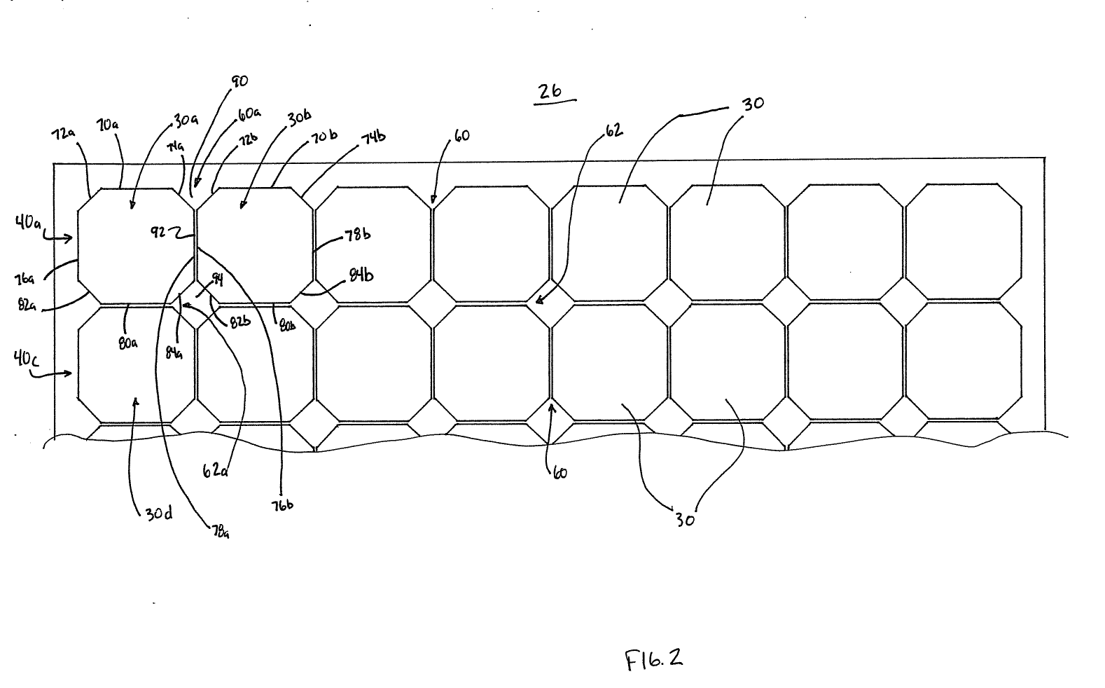

The PV cells 30 are identical in size and shape, and are uniformly distributed along the PV laminate. As a result, identical uniform spacings are defined between the PV cells 30. FIG. 2 illustrates a portion of the PV laminate 26 in greater detail, including the first row 40a of the PV cells 30, as well as an immediately adjacent row 40c. Adjacent ones of the PV cells 30 of the first row 40a are separated by a column spacing 60. For example, the first row 40a includes first and second PV cells 30a, 30b separated by a column spacing 60a. An identically sized and shaped column spacing 60b is defined between the second PV cell 30b and a third PV cell 30c immediately adjacent the second PV cell 30b in the first row 40a. Similar column spacings 60 are established between adjacent PV cells of the remaining rows 40, for example as illustrated in FIG. 2 for the PV cells 30 of the immediately adjacent row 40c. Further, a row spacing 62 is established between adjacent ones of the PV cells 30 from adjacent rows 40. FIG. 2 illustrates a first row spacing 62a between the first PV cell 30a of the first row 40a, and fourth PV cell 30d of the immediately adjacent row 40c that is otherwise immediately adjacent the first PV cell 30a. Once again, the row spacings 62 can all be identical in size and shape, and can further be identical to the column spacings 60.

With the above conventions in mind, the column spacings 60 and the row spacing 62 are uniform and identical in shape in some embodiments, with the particular shape being generated as a function of a shape of the PV individual cells 30. For example, FIG. 2 identifies the first PV cell 30a as having a shaped perimeter including a leading end segment 70a, opposing leading side segments 72a, 74a, opposing side segments 76a, 78a, a trailing end segment 80a, and opposing trailing side segments 82a, 84a. The second PV cell 30b has an identically shaped perimeter, with corresponding perimeter segments identified in FIG. 2 with similar numbers and the suffix “b”. Thus, the first column spacing 60a is defined between the leading side segment 74a of the first PV cell 30a and the leading side segment 72b of the second PV cell 30b; between the side segments 78a and 76b; and between the trailing side segment 84a and the trailing side segment 82b. In light of the octagonal-like shape of the PV cells 30, then, the first column spacing 60a includes or is defined by a leading portion 90, an intermediate portion 92, and a trailing portion 94. With the but one acceptable configuration of FIG. 2, the leading portion 90 tapers in width from the leading end segments 70a, 70b to the intermediate portion 92; conversely, the trailing portion 94 increases in width from the intermediate portion 92 to the trailing end segments 80a, 80b. As described below, features of the frame 24 (FIG. 1A) can be shaped in accordance with a shape of the column spacings 60. As a point of reference, while the PV cells 30 are illustrated as being generally octagonal in shape, a wide variety of other shapes are also applicable in accordance with principles of the present disclosure (e.g., square, rectangular, circular, non-symmetrical, etc.), with the resultant column spacings 60 and row spacings 62 having shape(s) differing from those shown.

Returning to FIGS. 1A and 1B, and with the above understanding of the PV laminate 26 in mind, the frame 24 generally includes framework 100 adapted to encompass the perimeter 34 of the PV laminate 26. In some constructions, the frame 24 further includes one or more arms 102 extending from the framework 100 and configured to facilitate arrangement of the PV laminate 26 at a desired orientation relative to an installation surface as described below. Regardless, the framework 100 includes at least a first frame member 104 incorporating one or more drainage features as described below. As a point of reference, while FIG. 1B illustrates the framework 100 as including four frame members 104-110, a variety of other configurations are also acceptable.

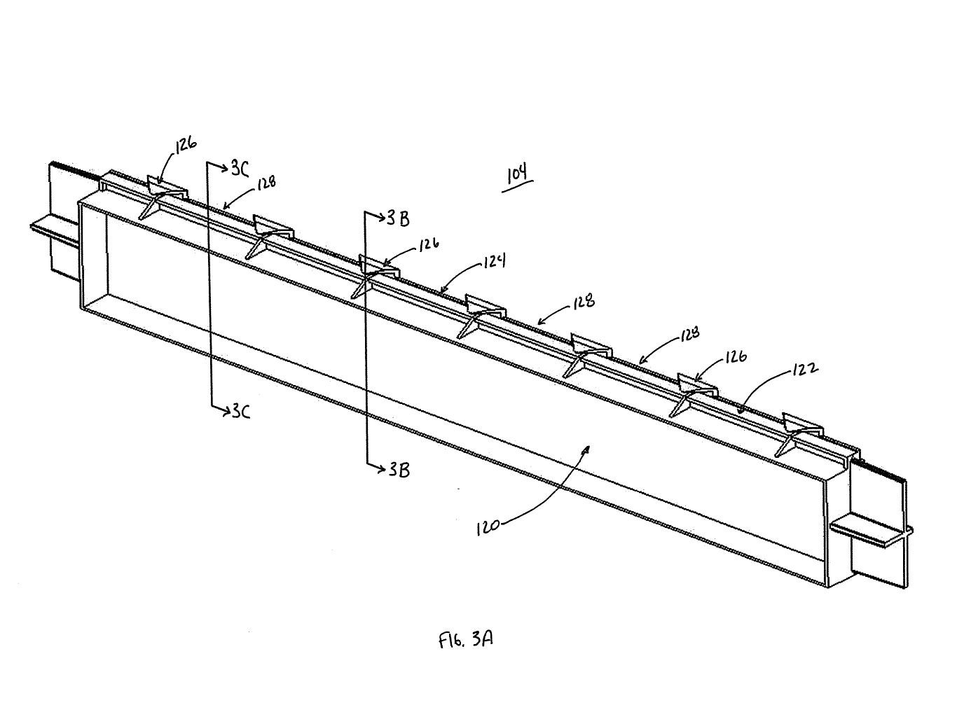

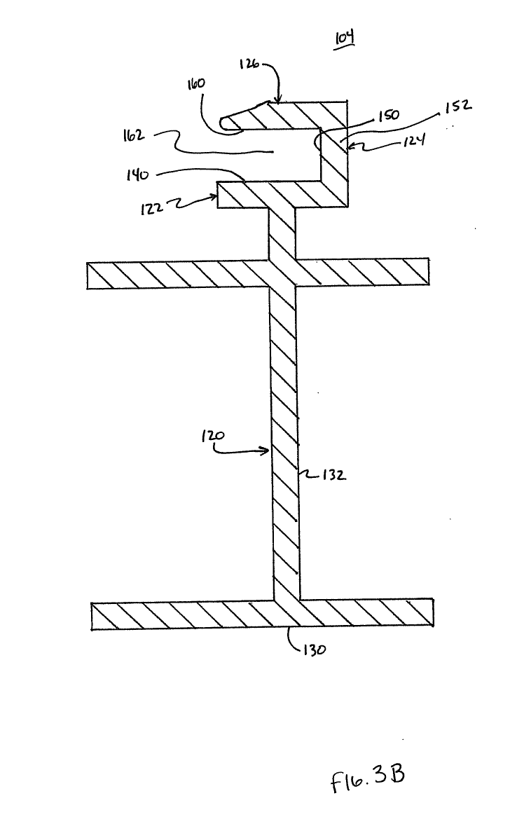

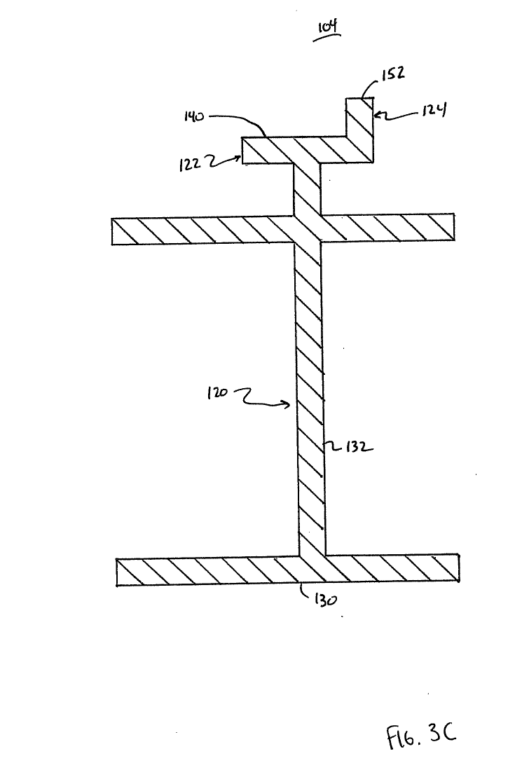

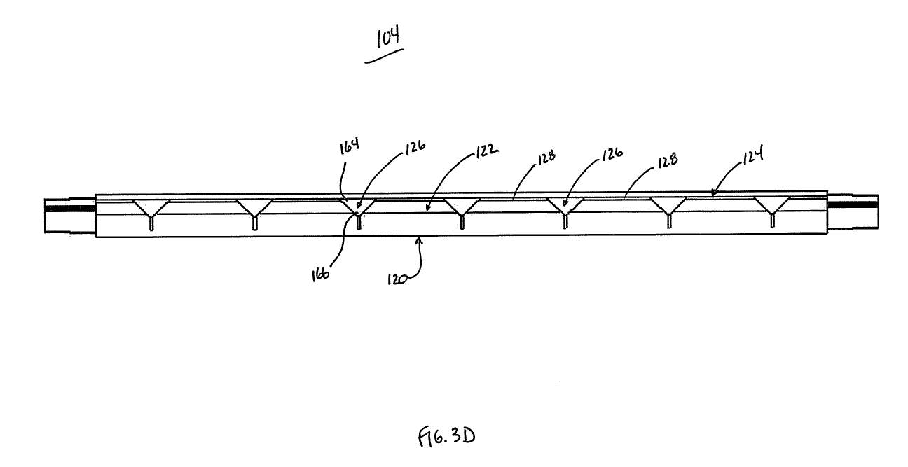

The first frame member 104 is shown in greater detail in FIG. 3A, and includes a main body 120, a ledge 122, a shoulder 124, and a plurality of spaced fingers 126. The ledge 122 extends from the main body 120, with the shoulder 124 projecting from the ledge 122 in a direction opposite the main body 120. The fingers 126 extend from the shoulder 124 opposite the ledge 122, and establish a plurality of gaps or drainage features 128. In this regard, the fingers 126 are positioned and shaped so as to minimize shading concerns upon final assembly.

The main body 120 can assume a variety of forms or shapes appropriate for imparting structural rigidity to the frame member 104, and in some embodiments is akin to an I-beam in cross-section as reflected in FIGS. 3B and 3C. Regardless, the main body 120 forms or generally establishes a lower face 130 and an exterior face 132.

The ledge 122 projects inwardly relative to the exterior face 132 at a location opposite the lower face 130. For example, in some constructions, the ledge 122 is generally perpendicular relative to a plane of the exterior face 132. To this end, the ledge 122 forms or establishes a support surface 140 for receiving a portion of the PV laminate 26 (FIG. 1A) as described below.

The shoulder 124 projects upwardly from the ledge 122, and is generally co-planar with the exterior face 132. Thus, the shoulder 124 can be generally perpendicular relative to the support surface 140 of the ledge 122. With this arrangement, then, the shoulder 124 forms or establishes a stop surface 150. In some embodiments, a height of the shoulder 124 (i.e., dimension of extension from the support surface 140) is selected as a function of a thickness of the PV laminate 26 (FIG. 1B). As best shown in FIG. 3C, the shoulder 124 terminates at an upper face 152 opposite the ledge support surface 140, with the upper face 152 being “exposed” along the gaps 128 (FIG. 3A). The height of the stop surface 150 can thus be defined as a distance between the support surface 140 and the upper face 152, and is selected to be slightly less than a nominal thickness of the PV laminate 26 in some embodiments. As described below, with this construction, the stop surface 150 is available for desirably aligning and maintaining the PV laminate 26 relative to the ledge 122, but does not present an overt impediment to drainage of liquid from the PV laminate 26.

FIGS. 3A and 3B illustrate each of the fingers 126 as extending from the shoulder 124 opposite the ledge support surface 140, and projecting inwardly relative to the exterior face 132. Regardless, the fingers 126 each define a retention surface 160 (FIG. 3B) that combines with the ledge support surface 140 to form a capture zone 162 (FIG. 3B) for receiving an edge of the PV laminate 26 (FIG. 1A). As a point of reference, the fingers 126 are formed as extensions from or beyond the upper face 152 of the shoulder 124, with the upper face 152 being generally indicated in FIG. 3B, but more clearly shown in FIG. 3C. With embodiments in which the first frame member 104 is provided as a homogenous, integral component, the upper face 152 of the shoulder 124 is essentially “covered” or non-existent along the fingers 126.

As best shown in FIG. 3D, in some constructions, the fingers 126 are identical, each having a tapered shape. For example, each of the fingers 126 includes or is defined by a base end 164 and a free end 166. The base end 164 is attached to (or formed by) the shoulder 124, with the free end 166 being formed opposite the shoulder 124. The fingers 126 can each taper in shape in extension from the base end 164 to the free end 166.

The tapered, triangular-like shape reflected in FIG. 3D is but one acceptable configuration for the fingers 126. A wide variety of other shapes, either symmetrical or non-symmetrical, are also acceptable. Further, while the fingers 126 have been described as being identical, in other constructions, one or more of the fingers 126 can have a differing shape and/or size. Along these same lines, while FIG. 3D illustrates the first frame member 104 as having seven of the fingers 126, any other number, either greater or lesser, is also acceptable.

With continued reference to FIG. 3D, the fingers 126 are uniformly spaced along the shoulder 124, with the gaps 128 thus having a uniform size or dimension.

In this regard, a dimension of the gaps 128 is selected in accordance with an arrangement of the PV cells 30 (FIG. 2) as described below.

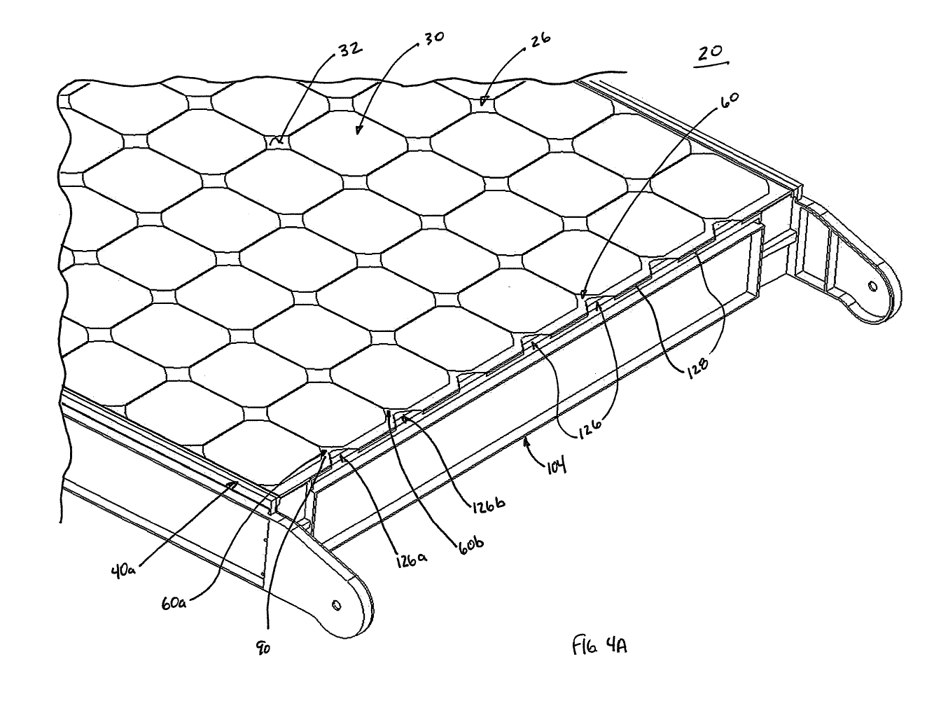

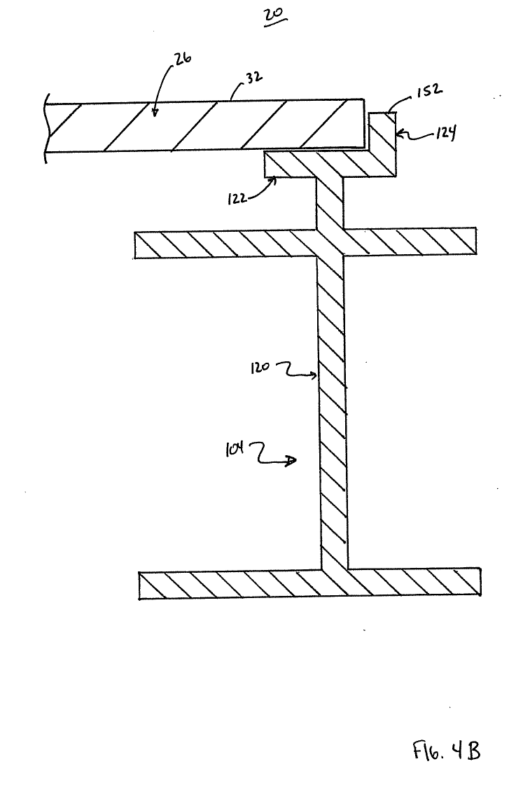

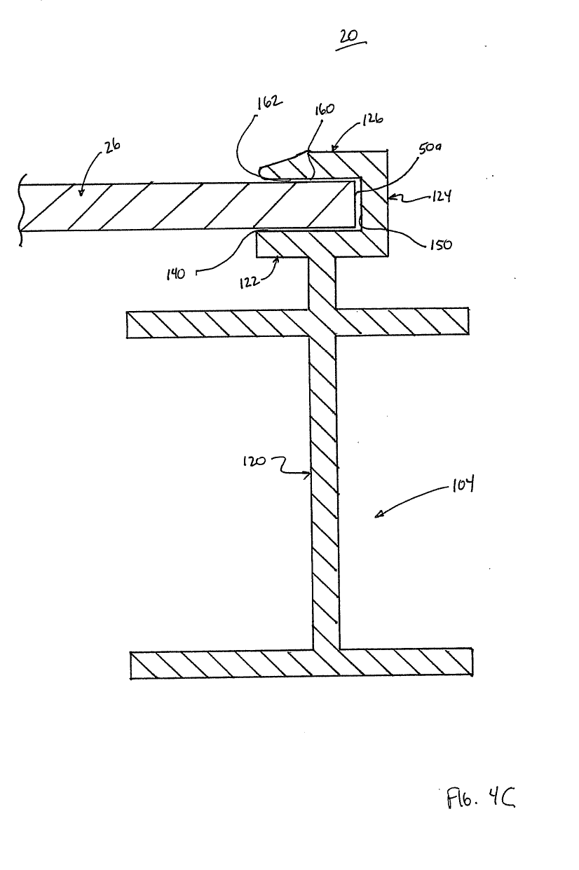

More particularly, FIG. 4A illustrates a portion of the PV module 20 upon final assembly, including an interface between the first frame member 104 and the PV laminate 26. The first perimeter end edge 50a of the PV laminate 26 is mounted to the first frame member 104, with individual ones of the fingers 126 being aligned with respective ones of the column spacings 60 established by the first row 40a of the PV cells 30. For example, the first finger 126a is aligned with the first column spacing 60a, the second finger 126b is aligned with the second column spacing 60b, etc. Further, the tapered shape of the fingers 126 corresponds with the tapered shape associated with the leading portion 90 of the corresponding column spacings 60.

That is to say, the generally triangular shape of the fingers 126 corresponds with the generally triangular shape of the leading portion 90 of the column spacings 60. With this arrangement and shape selection, the fingers 126 present minimal, if any, shading concerns relative to the PV cells 30 of the first row 40a.

For example, where the PV module 20 is mounted to an installation surface such that the first frame member 104 is facing to the south (for northern hemisphere installations; alternatively, to the north for southern hemisphere installations), as the sun sets, sunlight will be directed toward the PV module 20 at an ever-decreasing angle. In other words, as the time of day approaches dusk, sunlight will approach a more parallel relationship relative to the front face 32 of the PV laminate 26. During these later day periods, then, the fingers 126 may cast a partial shadow onto the front face 32. However, because the fingers 126 are aligned relative to, and shaped in accordance with, the column spacings 60 of the first row 40a, these so-created shadows will not fall directly onto the PV cells 30 of the first row 40a; instead, the shadows will primarily be cast within the column spacing 60, thereby optimizing the amount of sunlight captured by the PV cells 30. As compared to conventional PV module configurations, then, the frame 24 of the present disclosure more fully optimizes the ground coverage ratio (GCR) provided by the PV module 20.

In addition to optimizing the GCR, the first frame member 104 facilitates drainage of liquid from the front face 32 of the PV laminate 26. Liquid (and entrained dirt or debris) can freely flow from the front face 32 via one or more of the gaps 128, especially with constructions in which the first frame member 104 is arranged “below” other portions of the framework 100 so that gravity will naturally induce drainage through the gap(s) 128. FIG. 4B provides a partial cross-section of the PV module 20 taken along one of the gaps 128. As shown, the upper surface 152 of the shoulder 124 is slightly below or offset from the front face 32 of the PV laminate 26. Thus, the shoulder 124 will not prevent or impede drainage of liquid from the front face 32. To support and/or align the PV laminate 26, however, a height of the shoulder is at least 50% of the thickness of the PV laminate 26. Alternatively, the shoulder 124 can be aligned with or extend slightly above the front face 32. As a point of clarification, FIG. 4C illustrates assembly of the PV laminate 26 to the first frame member 104 along one of the fingers 126. As shown, the first perimeter end edge 50a is located in the capture zone 162 between the support surface 140 of the ledge 122 and the retention surface 160 of the finger 126, with the stop surface 150 of the shoulder 124 ensuring a desired spatial position of the first perimeter end edge 50a. An adhesive (not shown) can be employed to effectuate a more complete attachment between the PV laminate 26 and the first frame member 104.

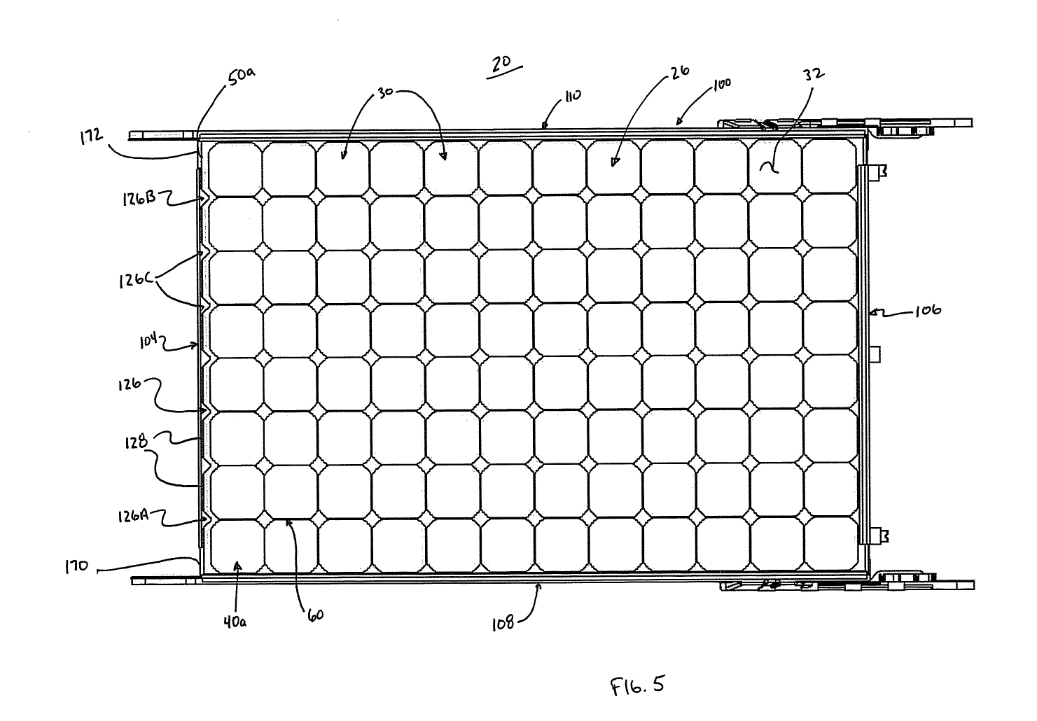

With reference to FIG. 5, upon final assembly, one of the fingers 126 is provided for each of the column spacings 60 of the first row 40a. Stated otherwise, the first frame member 104 can be defined as having opposing, first and second ends 170, 172 that are attached to opposing ones of the frame members 108, 110. For example, the first end 170 is attached to the third side frame member 108, and the second end 172 is attached to the fourth frame member 110. With these conventions in mind, the fingers 126 can be described as including a first end finger 126A, a second end finger 126B, and a plurality of intermediate fingers 126C. The first end finger 126A is located most proximate the first end 170, whereas the second end finger 126B is proximate the second end 172. The intermediate fingers 12C are disposed between the first and second end fingers 126A, 126B in a uniformly-spaced fashion (as dictated by the uniformly spaced PV cells 30 of the first row 40a) in establishing the gaps 128. Thus, multiple ones of the gaps 128 are formed for rapid liquid drainage. Further, the fingers 126 collectively provide sufficient surface area for retention or attachment of the first perimeter end edge 50a of the PV laminate 26, yet present minimal, if any, shading implications relative to the PV cells 30. In some embodiments, then, the number of fingers 126 corresponds with the number of PV cells 30 of the first row 40a; in particular, for a PV laminate 26 having n cells 30 in the first row 40a, the first frame member 104 has n-1 fingers 126. Other relationships can alternatively be employed.

As indicated above, in some embodiments the PV module 20 naturally facilitates drainage of liquid from the front face 32 of the PV laminate 26 by spatially positioning the first frame member 104 “below” other members of the framework 100. For example, with the one embodiment of FIGS. 1A and 1B, the frame 24 is configured to facilitate arrangement of the PV laminate 26 at a tilted or sloped orientation relative to a substantially flat installation surface (e.g., maximum pitch of 2:12), such as a rooftop (commercial or residential) or ground mount, with the first frame member 104 serving as a lowermost “side” of the framework 100. The arms 102 serve to orient the framework 100, and thus the PV laminate 26 maintained thereby, at the tilted or sloped orientation.

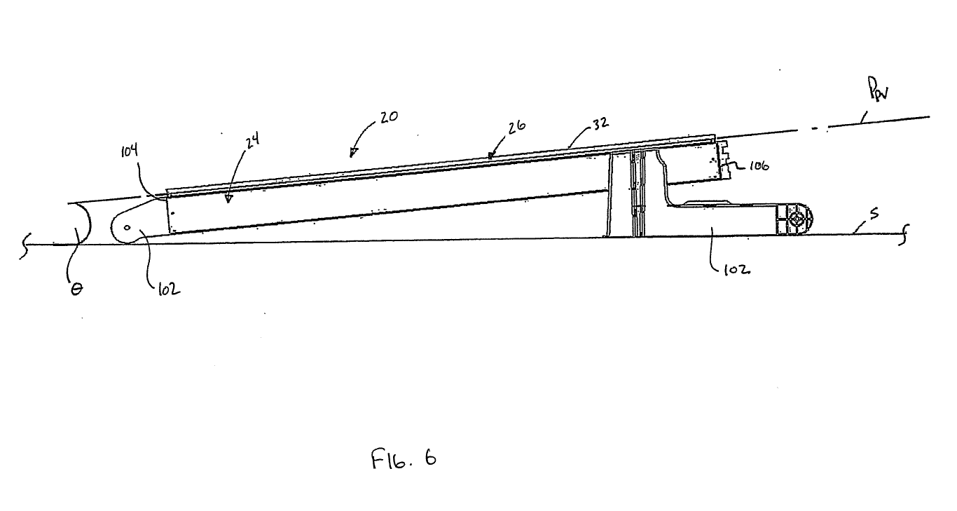

The tilted arrangement is further explained with reference to FIG. 6 that otherwise provides a simplified illustration of the PV module 20 relative to a flat, horizontal surface S. Though hidden in the view of FIG. 6, a location of the PV laminate 26 is generally indicated, as is a plane P_{PV} of the PV laminate 26 that is otherwise established by the front face 32. Relative to the arrangement of FIG. 6, the frame 24 supports the PV laminate 26 relative to the flat surface S at a slope or tilt angle θ. The tilt angle θ can otherwise be defined as an included angle formed between the PV laminate plane P_{PV} and a plane of the flat surface S. In some embodiments, the arms 102 (two of which are shown in FIG. 6) combine to define a support face at which the PV module 20 is supported against, and relative to, the flat surface S, with the tilt angle θ being similarly defined between the PV laminate P_{PV} and a plane of the support face. Regardless, with some constructions, the frame 24 is configured to support the PV laminate 26 at a tilt angle θ in the range of 1°-30°, in some embodiments in the range of 3°-7°, in yet other embodiments at 5°. As a point of reference, with tilted PV solar collection installations, the PV laminate 26 is desirably positioned so as to face or tilt southward (in northern hemisphere installations). Given this typical installation orientation, then, the first frame member 104 (referenced generally) can be referred to as a leading or south frame member, and the second frame member 106 (referenced generally) can be referred to as a trailing or north frame member. In other embodiments, however, the frame 24 can be configured to maintain the PV laminate 26 in a generally parallel relationship relative to the flat surface S. Further, the tilted arrangement can be facilitated by one or more components apart from the arms 102. Thus, with other constructions in accordance with the present disclosure, one or more of the arms 102 can be altered or omitted.

Returning to FIGS. 1A and 1B, the framework 100 can assume a variety of forms apart from the above and appropriate for encasing the perimeter 34 of the PV laminate 26, as well as establishing the optional tilt angle θ (FIG. 6). In some embodiments, the frame members 104-110 are separately formed and subsequently assembled to one another and the PV laminate 26 in a manner generating a unitary structure upon final construction. Alternatively, other manufacturing techniques and/or components can be employed such that the framework 100 reflected in FIGS. 1A and 1B is in no way limiting.

In some embodiments, the above-described features provided with the first frame member 104 are generated by molding the first frame member 104 from plastic. With plastic molding, such as injection plastic molding, the resultant frame member 104 is not subject to the constant, two-dimensional cross-section limitations associated with metal extrusions. Thus, as compared with a traditional extruded aluminum frame, the first frame member 104 can incorporate a more robust design (e.g., the I-beam shape described above). Further, by forming the first frame member 104 as a molded plastic part, no secondary operations are required to form the fingers 126. That is to say, unlike a traditional extruded aluminum frame that must be machine cut to define features that might otherwise be akin to the fingers 126/gaps 128, aspects of the present disclosure whereby the first frame member 104 is a plastic molded part in which the ledge 122, the shoulder 124, and the fingers 126 are integrally formed, the first frame member 104 can quickly be manufactured on a mass-production basis with no additional operations/expenses. In some embodiments, each of the frame members 104-110 are injection molded, plastic parts. In yet even other embodiments, an entirety of the frame 24 is plastic such as injection molded PPO/PS (Polyphenylene Oxide co-polymer/polystyrene blend) or PET (Polyethylene Terephthalate). However, features in accordance with the principles of the present disclosure can be provided with other materials, such that the plastic or polymeric construction is in no way limiting.

While the drainage features have been described as being provided as part of the first frame member 104, in other optional constructions, similar drainage-type features can be incorporated into one or more of the remaining frame members 106-110. Thus, for example, the third frame member 108 can incorporate a plurality of spaced fingers as described above, aligned with, and commensurate in size and shape with, the row spacings 62 provided along the first column 42a. Along these same lines, another optional construction includes each of the frame members 104-110 having or forming the spaced fingers as described above.

Although the present disclosure has been described with reference to preferred embodiments, workers skilled in the art will recognize that changes can be made in form and detail without departing from the spirit and scope of the present disclosure.

What is claimed is:

1. A photovoltaic module comprising:
a photovoltaic device including a photovoltaic laminate defining a perimeter and a front face, the photovoltaic laminate maintaining a plurality of photovoltaic cells at the front face, the plurality of photovoltaic cells arranged in rows including a first row formed immediately adjacent a first perimeter end edge of the photovoltaic laminate, wherein adjacent ones of the photovoltaic cells of the first row are separated by a column spacing; and
a frame assembled to and maintaining the photovoltaic laminate, the frame including a first frame member comprising:
a ledge,
a plurality of spaced fingers connected to, and spaced from, the ledge;
wherein upon final assembly, the first perimeter end edge is mounted between the ledge and the fingers, and one of the fingers is aligned with one of the column spacings of the first row.

2. The photovoltaic module of claim 1, wherein at least two of the fingers are aligned with two of the column spacings of the first row, respectively.

3. The photovoltaic module of claim 1, wherein all of the fingers are aligned with respective ones of the column spacings of the first row.

4. The photovoltaic module of claim 1, wherein the fingers each include a base end connected to the ledge and a free end opposite the base end, and further wherein each of the fingers taper in width from the base end to the free end.

5. The photovoltaic module of claim 1, wherein the first row includes a first photovoltaic cell adjacent a second photovoltaic cell, the first and second photovoltaic cells combining to define a leading portion of a shape of the corresponding column spacing, with the leading portion being defined immediately adjacent the first perimeter end edge, and further wherein a shape of at least one of the fingers corresponds with a shape of the leading portion.

6. The photovoltaic module of claim 1, wherein the frame further includes second and third frame members assembled to opposing, perimeter side edges, respectively, the photovoltaic laminate, and further wherein the first frame member includes a first end mounted to the second frame member and an opposing second end mounted to the third frame member, and further wherein the plurality of fingers are uniformly spaced between the first and second ends.

7. The photovoltaic module of claim 6, wherein the first row of photovoltaic cells includes n photovoltaic cells and the plurality of fingers includes n-1 fingers.

8. The photovoltaic module of claim 1, wherein the first frame member further includes a shoulder interconnecting the plurality of fingers with the ledge.

9. The photovoltaic module of claim 8, wherein a gap is defined between an adjacent pair of fingers, and further wherein the shoulder extends along the gap.

10. The photovoltaic module of claim 9, wherein the shoulder has a height, at least along the gap, of at least one-half a thickness of the photovoltaic laminate.

11. The photovoltaic module of claim 10, wherein the shoulder has a height approximating a thickness of the photovoltaic laminate at least along the gap.

12. The photovoltaic module of claim 9, wherein the plurality of fingers includes a first end finger adjacent a first end of the first frame member, a second end finger adjacent a second, opposite end of the first frame member, and a plurality of intermediate fingers disposed between the first and second end fingers, and further wherein the end fingers and the intermediate fingers combine to define a plurality of gaps, and even further wherein the shoulder extends from the ledge at a uniform height along each of the plurality of gaps.

13. The photovoltaic module of claim 1, wherein the first frame member is entirely formed of plastic.

14. The photovoltaic module of claim 13, wherein the frame is entirely formed of plastic.

15. The photovoltaic module of claim 1, wherein the photovoltaic cells are further arranged in columns including a first column formed immediately adjacent a first perimeter side edge of the photovoltaic laminate perpendicular to the first perimeter end edge, adjacent ones of the photovoltaic cells of the first column being separated by a row spacing, and further wherein the frame includes a second frame member comprising:
a ledge; and
a plurality of spaced fingers connected to, and spaced from, the ledge of the second frame member;
wherein upon final assembly, the first perimeter side edge is mounted between the ledge and the fingers of the second frame member, and ones of the fingers of the second frame member are aligned with respective ones of the row spacings of the first column.

16. A method of making a photovoltaic module, the method comprising:
providing a photovoltaic device including a photovoltaic laminate defining a perimeter and a front face, the photovoltaic laminate maintaining a plurality of photovoltaic cells at the front face, the photovoltaic cells arranged into rows including a first row formed immediately adjacent a first perimeter end edge of the photovoltaic laminate;
molding a first frame member from plastic such that the first frame member includes a ledge and a plurality of spaced fingers connected to, and spaced from, the ledge; and
assembling the photovoltaic laminate to the frame including inserting the first perimeter end edge between the ledge and the fingers.

17. The method of claim 16, wherein adjacent ones of the photovoltaic cells of the first row are separated by a column spacing, and further wherein assembling the photovoltaic laminate to the frame includes aligning one of the fingers with one of the column spacings of the first row.

18. The method of claim 16, wherein molding the first frame member includes injection molding the first frame member.

19. The method of claim 16, wherein molding the first frame member includes forming the first frame member to form a first end finger adjacent a first end of the first frame member, a second end finger formed adjacent a second end of the first frame member and opposite the first end, and a plurality of intermediate fingers disposed between the first and second end fingers, wherein the intermediate fingers are uniformly disposed between the first and second end fingers.

20. The method of claim 16, wherein assembling the photovoltaic laminate to the frame includes aligning each of the column spacings with respective ones of the fingers.
